(19) United States
(12) Patent Application Publication
(10) Pub. No.: US 2008/0138980 A1
(43) Pub. Date: Jun. 12, 2008

(54) METHOD FOR MANUFACTURING A METAL PATTERN OF A SEMICONDUCTOR DEVICE

(76) Inventor: Kyeong-Sik Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/939,338

(22) Filed: Nov. 13, 2007

(30) Foreign Application Priority Data
Dec. 12, 2006 (KR) 10-2006-0126097

(51) Int. Cl. H01L 21/4763

(52) U.S. Cl. 438/669; 257/E21.496

(57) ABSTRACT

A method for manufacturing a metal pattern of a semiconductor device capable of preventing generation of a ring defect in a metal pattern by performing a stuffing process for making increasing the density of an anti-reflection-coating using O₂ gas or N₂ gas.

This application claims priority under 35 U.S.C. 119 to Korean Patent Application No. 10-2006-0126097 (filed on Dec. 12, 2006), which is hereby incorporated by reference in its entirety.

### BACKGROUND

Metal patterns may be formed to electrically connect devices or used between wirings in a manufacturing process of a semiconductor device. Metal patterns may be composed of various metal materials such as aluminum (Al), tungsten (W), copper (Cu), etc. Aluminum has been applied as a metal pattern.

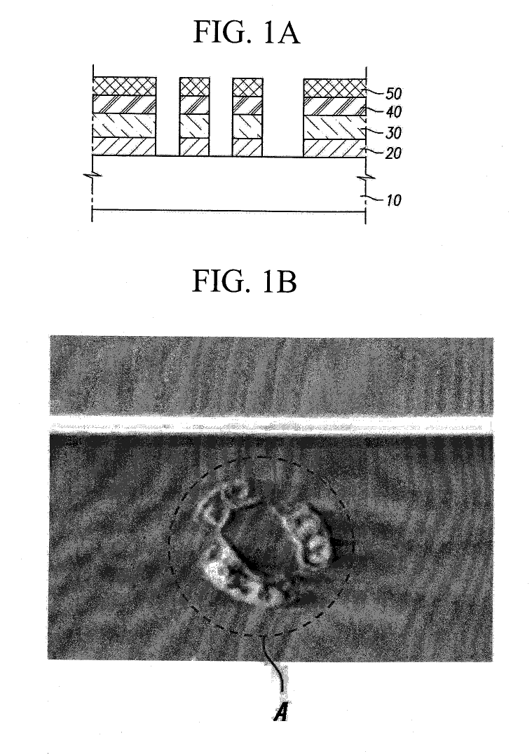

As illustrated in example FIG. 1, a semiconductor device may include glue layer 20 formed on and/or over semiconductor substrate 10. Metal layer 30 composed of aluminum may be formed on and/or over glue layer 20. Metal layer 30 may function as a signal line and a power line for the semiconductor device.

In order to lower the reflectivity of the aluminum in metal layer 30, anti-reflection coating (ARC) 40 having a predetermined thickness and which may be composed titanium nitride (TiN) may be stacked on and/or over metal layer 30 aluminum film. A photolithographic process for forming a photoresist may be performed to form photoresist pattern 50 on and/or over anti-reflection coating 40.

Glue layer 20, metal layer 30 and anti-reflection-coating 40 may then be etched using photoresist pattern 50 as a mask until the uppermost surface of semiconductor substrate 10 is exposed to form a metal pattern.

As illustrated in example FIG. 1B, since anti-reflection-coating 40 is composed of TiN, during formation of the meta pattern, an acidic developer may be infiltrated into anti-reflection-coating 40 which causes a reaction between anti-reflection-coating 40 and metal layer 30 at a depressed point of a grain boundary, thereby generating ring defect “A” and corroding the aluminum in metal layer 30. Particularly, an etchant used in a development process for forming photoresist pattern 50 is infiltrated below anti-reflection-coating 40 to corrode aluminum in metal layer 30 and the corroded portion of metal layer 30 may be oxidized in a rinse process using de-ionized water (DIW) to generate Al₂O₃ oxidation by-products. The Al₂O₃ oxidation by-products may serve as an etch mask in an etching process of subsequent metal layer 30 to hinder the etching on the metal layer of the upper thereof so that the pattern (ring) defect of the aluminum metal wiring is generated. Also, a problem of bridging between the metal patterns is caused due to the ring defect.

### SUMMARY

Embodiments relate to a method for manufacturing a semiconductor device that prevents formation of a defect such as a ring defect in a metal pattern forming process due to the corrosion of a metal layer caused by the infiltration of an acidic developer into an anti-reflection-coating and the subsequent reaction of the anti-reflection-coating and the metal layer.

Embodiments relate to a method for manufacturing a metal pattern of a semiconductor device that can include at least one of the following steps: forming a barrier layer serving as a etch stop layer over a semiconductor substrate; forming a metal layer over the barrier layer; forming an anti-reflection-coating over the metal layer; increasing the density of the anti-reflection coating; and then performing an etching on the metal layer using a photoresist pattern as an etching barrier.

Embodiments relate to a method for manufacturing a metal pattern of a semiconductor device that can include at least one of the following steps: forming a barrier layer over a semiconductor substrate; sequentially forming a metal layer and an anti-reflection-coating over the barrier layer; enhancing the density of the anti-reflective coating; forming a photoresist pattern over the anti-reflective coating; etching the metal layer and the anti-reflection-coating using the photoresist pattern as an etching mask; and then removing the photoresist pattern and the anti-reflection-coating.

Embodiments relate to a method for manufacturing a metal pattern of a semiconductor device that can include at least one of the following steps: forming a barrier layer over a semiconductor substrate; forming a metal layer over the semiconductor substrate; forming an anti-reflection-coating including a Ti film and a TiN film over the barrier layer; enhancing the density of the TiN film; etching the metal layer and the anti-reflection-coating using a photoresist pattern as an etching mask; and then removing the photoresist pattern and the anti-reflection-coating.

### DRAWINGS

Example FIGS. 1A and 1B illustrate a method for manufacturing a metal pattern in a semiconductor device.

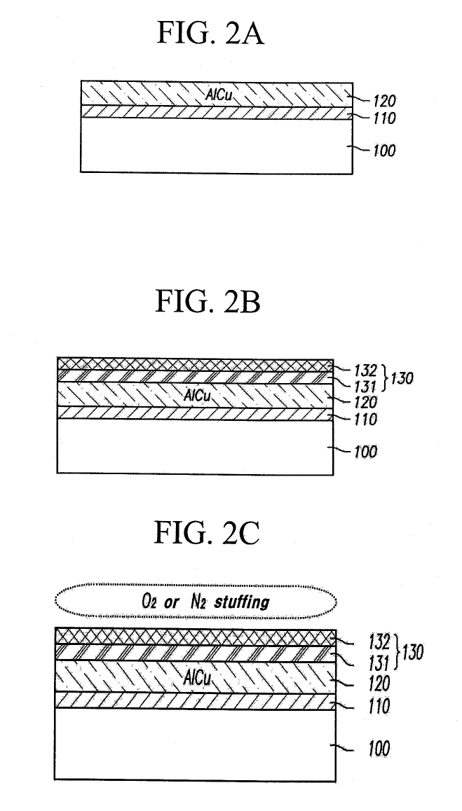

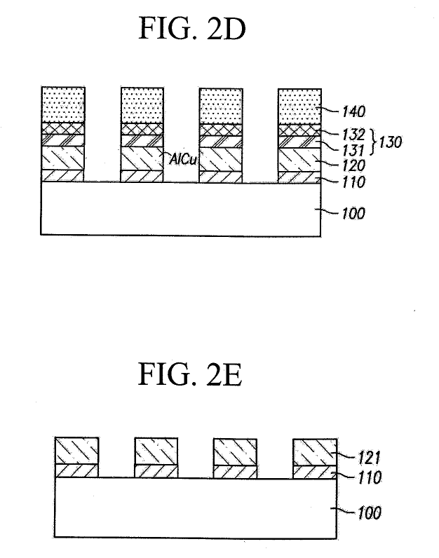

Example FIGS. 2A to 2E illustrate a method for manufacturing a metal pattern of a semiconductor device, in accordance with embodiments.

### DESCRIPTION

As illustrated in example FIG. 2A, a method for manufacturing a metal pattern of a semiconductor device may include forming barrier layer 110 on and/or over semiconductor substrate 100. Barrier layer 110 can function as an etch stop layer in a subsequent etching process(es). Barrier layer 110 can be composed of an amorphous film such as at least one of an SiN film, Ta—Si film and a Ta—Si—N film. Barrier layer 110 composed of a Ta—Si film can be formed by performing a sputtering method using Ta₅Si₃, which is Ta—Si alloy, as a target and selectively adding N₂ gas as an reaction gas. In the course of performing the sputtering using Ta₅Si₃, it can be formed of Ta—Si—N film such as Ta₃₆Si₁₄N₅₀.

In accordance with embodiments, an amorphous Ta—Si—N film can be used as the barrier layer 110. Because nitrogen is present, barrier layer 110 can be a dense layer so that chemical stability is improved, and thus, a reactivity with the etchant in the subsequent performed etching process can be reduced. Consequently, barrier layer 110 can serve as an etch stop layer.

As illustrated in example FIG. 2B, after forming barrier layer 110, metal layer 120 and anti-reflection-coating 130 can be sequentially formed on and/or over barrier layer 110.

Metal layer 120 can be formed by depositing at least one of Al and AlCu alloy as a target by at least one of a sputtering process and a plasma-enhanced chemical vapor deposition (PECVD) method and then planarizing metal layer 120 using at least one of an etch back process and a chemical mechanical polishing (CMP) process. Metal layer 120 can have a thickness of between approximately 6000 Å to 8000 Å.

Anti-reflection-coating 130 can have a multilayer/stacked structure including first metal film 131 and second metal film 132. First metal film 131 can be composed of Ti and second metal film 132 can be composed of TiN. First metal film 131 can be formed using Ti as a target by at least one of a self-ionized plasma sputtering (SIP) method and a hollow cathode magnetron (HCM) sputtering method.

Second metal film 132 can be formed using Ti as a target by at least one of a self-ionized plasma sputtering (SIP) method and a hollow cathode magnetron (HCM) sputtering method and injecting nitrogen gas into the process chamber after forming the Ti film. Second metal film 132 can be formed using a metal organic chemical vapor deposition (MOCVD) process. During the MOCVD process, a hydrogen radical from H₂ plasma supplied in the MOCVD process reacts with an organo-titanium precursor used as a Ti source material, for example, alkylamidotitanium derivatives such as tetrakis-dimethylamidotitanium (TDMAT) or tetrakis-diethylamidotitanium (TDEAT), to form the TiN film.

Anti-reflection-coating 130 can alternatively not be formed having a stacked structure of Ti film 131 and TiN film 132 but instead can be formed in at least one layers using general anti-reflection-coating materials other than oxides.

As illustrated in example FIG. 2C, after forming anti-reflection-coating 130, a stuffing process for making enhancing the density of TiN film 132 can be performed. The stuffing process on TiN film 132 can include a chamber having a furnace set in a temperature range of between 350° C. to 450° C. or alternatively providing semiconductor substrate 100 including anti-reflection-coating 130 in a CVD chamber. At least one of O₂ gas and N₂ gas is then injected into the furnance or the CVD chamber. If the stuffing process is performed on TiN film 132 by implanting O₂ gas or N₂ gas, TiN film 132 becomes more dense so that etchants used in a developing process and a photolithographic process can go through TiN film 132, thereby preventing chemical damage to metal layer 120.

As illustrated in example FIG. 2D, metal layer 120 and anti-reflection-coating 130 can be etched using photoresist pattern 140 as an etching barrier. The etchant does not corrode metal layer 120 in a developing process so that a ring-defect is not generated.

As illustrated in example FIG. 2E, the remaining photoresist pattern 140 and anti-reflection-coating 130 on and/or over patterned metal layer 121 can then be removed to expose the metal wirings.

In accordance with embodiments, a stuffing process can be performed on an anti-reflection-coating by implanting O₂ gas or N₂ gas to make the density of the anti-reflection-coating dense, making it possible to prevent the metal layer from being chemically damaged by the etchant used in a developing process, which is a subsequent process.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a barrier layer serving as a etch stop layer over a semiconductor substrate;
forming a metal layer over the barrier layer;
forming an anti-reflection-coating over the metal layer;
increasing the density of the anti-reflection coating; and
performing an etching on the metal layer using a photoresist pattern as an etching barrier.

2. The method of claim 1, wherein the barrier layer comprises an amorphous layer of at least one of SiN, Ta—Si and Ta—Si—N.

3. The method of claim 1, wherein the barrier layer comprises Ta—Si—N and is formed by adding N₂ gas as reaction gas in a sputtering process using Ta₅Si₃ as a target.

4. The method of claim 1, wherein forming the metal layer comprises:
depositing at least one of Al and an Al—Cu alloy at a thickness of between approximately 6000 Å to 8000 Å by at least one of a sputtering process and a plasma-enhanced chemical vapor deposition process; and then
planarizing the at least one of Al and an Al—Cu alloy by at least one of an etch back process and a chemical mechanical polishing process.

5. Then method of claim 1, wherein increasing the density of the anti-reflective coating is done by performing a stuffing process.

6. The method of claim 5, wherein the stuffing process is performed by injecting at least one of O₂ gas and N₂ gas into a CVD chamber.

7. The method of claim 5, wherein the stuffing process is performed by injecting at least one of O₂ gas and N₂ gas into a furnace set in a temperature range of between 350° C. to 450° C.

8. The method of claim 1, further comprising removing the anti-reflection-coating and the photoresist pattern.

9. The method of claim 8, removing the anti-reflection-coating and the photoresist pattern is done by performing an ashing process.

10. A method comprising:
forming a barrier layer over a semiconductor substrate;
sequentially forming a metal layer and an anti-reflection-coating over the barrier layer;
enhancing the density of the anti-reflective coating;
forming a photoresist pattern over the anti-reflective coating;
etching the metal layer and the anti-reflection-coating using the photoresist pattern as an etching mask; and then
removing the photoresist pattern and the anti-reflection-coating.

11. The method of claim 10, wherein the barrier layer comprises an amorphous film.

12. The method of claim 11, wherein the amorphous film comprises at least one of SiN, Ta—Si and Ta—Si—N.

13. The method of claim 10, wherein the barrier layer comprises an amorphous Ta—Si film.

14. The method of claim 13, wherein the amorphous Ta—Si film is formed by performing a sputtering method using a Ta—Si alloy as a target and selectively adding N₂ gas as a reaction gas.

15. The method of claim 14, wherein the Ta—Si alloy comprises Ta₅Si₃.

16. The method of claim 10, wherein forming the metal layer comprises:
depositing at least one of an Al film and an Al—Cu alloy film by at least one of a sputtering process and a plasma-enhanced chemical vapor deposition method; and then
planarizing the at least one of an Al film and an Al—Cu alloy film using at least one of an etch back process and a chemical mechanical polishing process.

17. The method of claim 16, wherein the at least one of an Al film and an Al—Cu alloy film has a thickness of between approximately 6000 Å to 8000 Å.

18. The method of claim 10, wherein the anti-reflection-coating has a multilayer structure including a first metal film and a second metal film provided over the first metal film.

19. The method of claim 10, wherein the first metal film comprises Ti and the second metal film comprises TiN.

20. A method comprising:
forming a barrier layer over a semiconductor substrate;
forming a metal layer over the semiconductor substrate;
forming an anti-reflection-coating including a Ti film and a TiN film over the barrier layer;
enhancing the density of the TiN film;
etching the metal layer and the anti-reflection-coating using a photoresist pattern as an etching mask; and then
removing the photoresist pattern and the anti-reflection-coating.
